(19) United States
(12) Patent Application Publication
(10) Pub. No.: US 2003/0160303 A1
(43) Pub. Date: Aug. 28, 2003

(54) Semiconductor chip mounting wafer

(75) Inventors: Taichi Hirokawa, Hyogo (JP); Heiji Kobayashi, Hyogo (JP)

Correspondence Address: McDERMOTT, WILL & EMERY, 600 13th Street N.W., Washington, DC, 20005-3096, US

(73) Assignee: MITSUBISHI DENKI KABUSHIKI KAISHA,

(21) Appl. No.: 10/327,889

(22) Filed: Dec. 26, 2002

(30) Foreign Application Priority Data
Feb. 28, 2002 (JP) 2002-053422(P)

(51) Int. Cl. H01L 23/544

(52) U.S. Cl. 257/620

(57) ABSTRACT

A plurality of semiconductor chips such as a dynamic random access memory are formed on a wafer. The semiconductor chips are partitioned by a dicing line region. A silicon oxide film is formed on the wafer. A corrugated groove is formed on an insulating film located in the dicing line region. A metal film such as barrier metal constituting the semiconductor chips is formed so as to cover a surface of the corrugated groove. A film stress of the metal film is dispersed in multiple directions. It is thereby possible to obtain a semiconductor chip mounting wafer capable of ensuring relaxing wafer warping and suppressing an electrostatic chuck error.

### BACKGROUND OF THE INVENTION

1. Field of the Invention

The present invention relates to a semiconductor chip mounting wafer, and more particularly to a semiconductor chip mounting wafer capable of relaxing the warping of the wafer.

2. Description of the Background Art

A semiconductor chip is formed by performing to a wafer many treatments such as a heat treatment step, a film formation step, a photolithography step and an etching step. Through these steps, semiconductor elements, wirings connecting the semiconductor elements and the like required for the chip to function as a semiconductor chip are formed.

Recently, wafer warping which occurs in a wafer manufacturing process becomes a problem following the microfabrication of semiconductor devices. For example, if a predetermined conductive film is formed on the wafer so as to form a metal wiring, the wafer is warped in a certain direction by the film stress of the conductive film itself.

A technique for eliminating such wafer warping is described in, for example, Japanese Patent Laying-Open No. 11-186119, which will be described hereinafter. First, as shown in FIG. 17, a plurality of semiconductor chips 104 are formed on a wafer 102. A dicing line region 106 is provided between two adjacent semiconductor chips 104 and 104.

In dicing line region 106, a groove 108 is formed on a semiconductor substrate 101 (wafer 102) as shown in FIG. 18. In semiconductor chip manufacturing steps, if the film stress of a film formed on wafer 102 is relatively high, a force for warping wafer 102 is relaxed by groove 108.

As can be seen, the warping of wafer 102 has been conventionally eliminated by providing groove 108 on dicing region 106.

However, the above-mentioned conventional semiconductor chip mounting wafer has the following disadvantages.

In semiconductor chip mounting wafer 102, the rear surface of wafer 102 is subjected to a polishing treatment before dicing, and wafer 102 is thereby made thinner. Due to this, conventional groove 108 is insufficient to eliminate wafer warping and the problem that wafer 102 tends to be warped by the film stress of a metal film or the like for a multilayer wiring formed on wafer 102 still remains unsolved.

Moreover, if, for example, semiconductor chip 104 is electrically measured in a wafer state prior to dicing or if the thickness of a predetermined film formed on wafer 102 is measured, then it is disadvantageously impossible to hold wafer 102 by an electrostatic chuck (an electrostatic chuck error occurs).

### SUMMARY OF THE INVENTION

The present invention has been made to solve the above-mentioned disadvantages. An object of the present invention is to provide a semiconductor chip mounting wafer capable of ensuring relaxing wafer warping and thereby suppressing an electrostatic chuck error.

According to the present invention, a first semiconductor chip mounting wafer includes a plurality of chip regions, a dicing line region, an insulating film, a corrugated groove section and a predetermined layer. Each of the plurality of chip regions has a semiconductor chip formed therein. The dicing line region is formed for cutting down the plurality of chip regions. The insulating film is formed so as to cover the plurality of chip regions and the dicing line region. The corrugated groove section is formed in a section of the insulating film located in the dicing line region. The predetermined layer for forming the semiconductor chips is formed on the insulating film including the corrugated groove.

According to this configuration, the corrugated groove is formed in the section of the insulating film located in the dicing line region and a metal film such as a barrier metal is formed so as to cover the surface of the corrugated groove, whereby the film stress of the metal film is dispersed in multiple directions. Besides, since the surface area of the corrugated groove becomes larger, the area of the groove capable of dispersing the film stress in the multiple directions increases. Even if the wafer becomes thinner and tends to be influenced by the film stress of the metal film, it is possible to sufficiently relax the stress acting on the wafer and to ensure reducing the warping of the wafer. In addition, as a result of relaxing wafer warping, the occurrence of an electrostatic chuck error is suppressed.

Specifically, at least two corrugated groove sections are preferably arranged in the dicing line region located between the two adjacent chip regions.

It is thereby possible to increase the surface area of the corrugated groove and to effectively relax the film stress.

According to one aspect of the present invention, a second semiconductor chip mounting wafer includes a plurality of chip regions, a dicing line region, an insulating film, a groove section, and a predetermined layer. Each of the plurality of chip regions has a semiconductor chip formed thereon. The dicing line region is formed for cutting down the plurality of chip regions. The insulating film is formed so as to cover the plurality of chip regions and the dicing line region. The groove section is formed in a section of the insulating film located in the dicing line region. The predetermined layer is formed on the insulating film including the groove section to form the semiconductor chips. The groove section includes a first section having a first width and a second section having a second width different from the first width in a cross section of the groove section.

According to this configuration, the groove section formed on the insulating film located in the dicing line region includes the first section having the first width and the second section having the second width, whereby the surface area of the groove section is larger than that of a groove section which would be formed to have the same width. By forming, for example, a metal film as the predetermined layer so as to cover the surface of the groove section, the region (area) of the groove section capable of dispersing the film stress increases. Therefore, even if the thickness of the wafer becomes thinner and tends to be influenced by the film stress, it is possible to sufficiently relax the stress acting on the wafer and to ensure reducing the warping of the wafer. In addition, as a result of reducing wafer warping, the occurrence of an electrostatic chuck error is suppressed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a semiconductor chip mounting wafer according to a first embodiment of the present invention;

FIG. 2 is a partially enlarged plan view of a part A shown in FIG. 1 in the first embodiment;

FIG. 3 is a cross-sectional view corresponding to a cross-sectional line III-III shown in FIG. 2 and showing one step of a manufacturing method for manufacturing the wafer shown in FIG. 1 in the first embodiment;

FIG. 4 is a cross-sectional view showing a step executed after the step shown in FIG. 3 in the first embodiment;

FIG. 5 is a cross-sectional view showing a step executed after the step shown in FIG. 4 in the first embodiment;

FIG. 6 is a cross-sectional view showing a step executed after the step shown in FIG. 5 in the first embodiment;

FIG. 7 is a partial plan view showing a step executed after the step shown in FIG. 6 in the first embodiment;

FIG. 8 is a cross-sectional view showing a step executed after the step shown in FIG. 7 in the first embodiment;

FIG. 9 is a cross-sectional view showing a step executed after the step shown in FIG. 8 in the first embodiment;

FIG. 10 is a partial plan view for explaining the relaxing of the warping of the wafer in the first embodiment;

FIG. 11 is a partial cross-sectional view for explaining the relaxing of the warping of the wafer in the first embodiment;

FIG. 12 is a cross-sectional view showing one step of another manufacturing method for the wafer shown in FIG. 1 in the first embodiment;

FIG. 13 is a cross-sectional view showing a step executed after the step shown in FIG. 12 in the first embodiment;

FIG. 14 is a partial cross-sectional view of a semiconductor chip mounting wafer according to a second embodiment of the present invention;

FIG. 15 is a cross-sectional view showing one step of a manufacturing method for the wafer shown in FIG. 14 in the second embodiment;

FIG. 16 is a cross-sectional view showing a step executed after the step shown in FIG. 15 in the second embodiment;

FIG. 17 shows a conventional semiconductor chip mounting wafer; and

FIG. 18 is a cross-sectional view corresponding to a cross-sectional line XVIII-XVIII shown in FIG. 17.

### DESCRIPTION OF THE PREFERRED EMBODIMENTS

First Embodiment

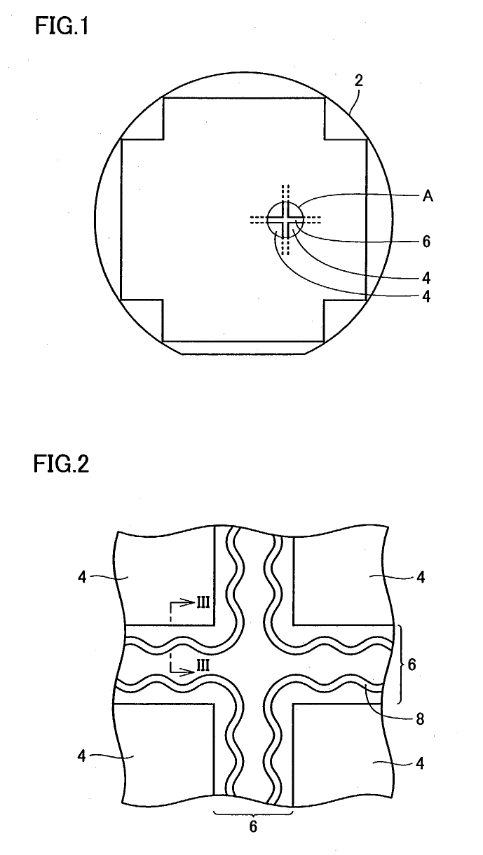

A semiconductor chip mounting wafer and a manufacturing method therefor according to the first embodiment of the present invention will be described. First, as shown in FIG. 1, a plurality of semiconductor chips 4 such as a dynamic random access memory (referred to as “DRAM” hereinafter) are formed on a wafer 2. Semiconductor chips 4 are partitioned from one another by dicing line regions 6.

As shown in FIG. 2, a corrugated groove 8 having a corrugated shape in a plan view is formed in dicing line regions 6. In this case, one continuous corrugated groove 8 is arranged for one semiconductor chip 4 to surround chip 4. Therefore, two corrugated grooves 8 are located at two adjacent semiconductor chips 4.

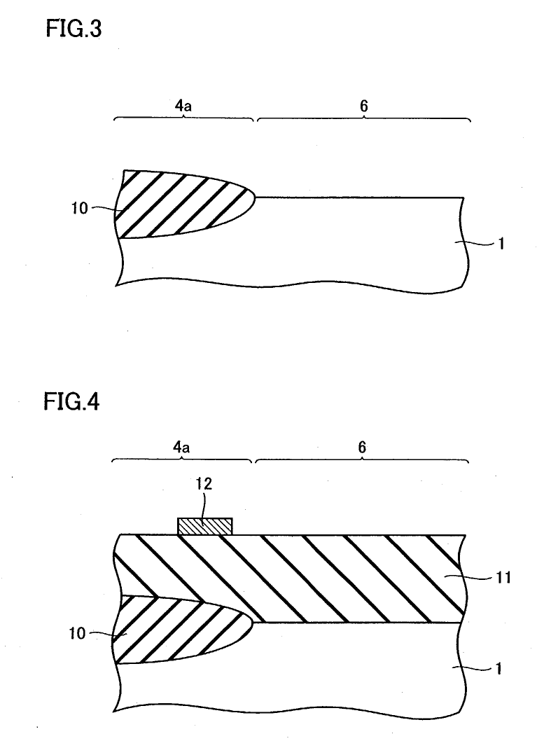

A method for manufacturing semiconductor chip mounting chip 2 described above will next be described. First, as shown in FIG. 3, a predetermined isolation oxide film 10 and the like are formed on the main surface of a semiconductor substrate 1 as the wafer, thereby forming a chip formation region 4a to form semiconductor chip 4. Dicing line region 6 is formed between two adjacent chip formation regions 4a and 4a.

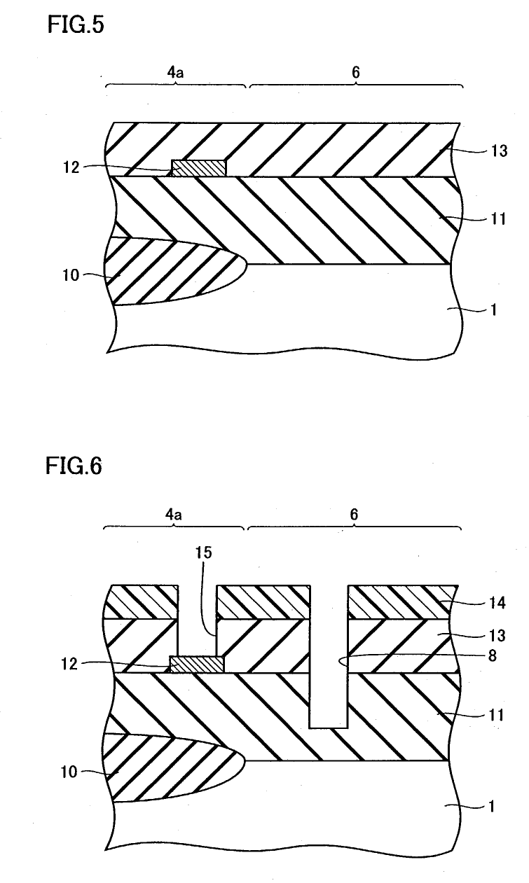

Next, as shown in FIG. 4, a silicon oxide film 11 is formed on semiconductor substrate 1 by, for example, a CVD (Chemical Vapor Deposition) method. A wiring 12 is formed on silicon oxide film 11. As shown in FIG. 5, a silicon oxide film 13 having a film thickness of 500 to 1000 nm (5000 to 10000 Å) is then formed on silicon oxide film 11 so as to cover wiring 12 by, for example, the CVD method.

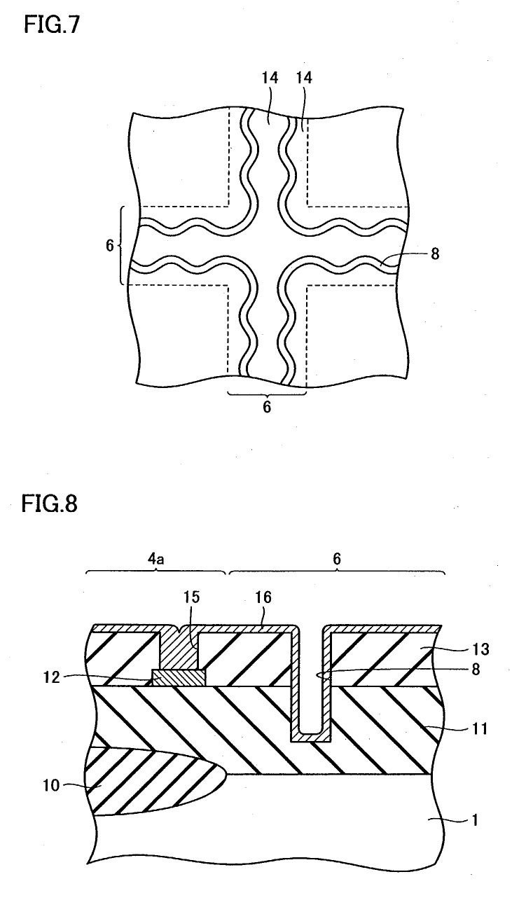

Thereafter, as shown in FIGS. 6 and 7, a photoresist 14 is formed to form a predetermined contact hole and a corrugated groove in silicon oxide film 13. Using photoresist 14 as a mask, silicon oxide films 13 and 11 are subjected to anisotropic etching, whereby a contact hole 15 which exposes the surface of wiring 12 is formed in chip formation region 4a and a corrugated groove 8 is formed in dicing line region 6.

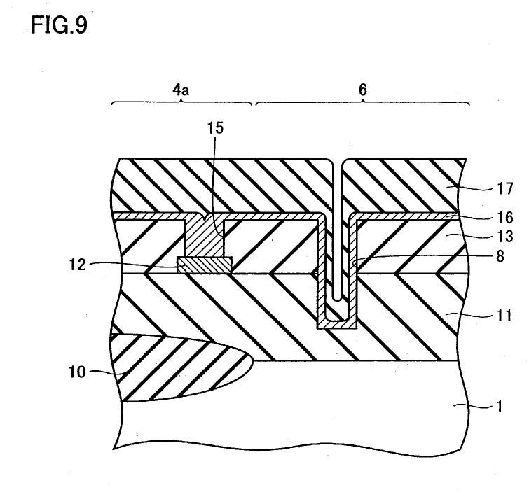

Next, as shown in FIG. 8, a predetermined metal film 16 is formed on silicon oxide films so as to embed contact hole 15 by, for example, a sputtering method. By performing predetermined photolithography and processing to metal film 16, a predetermined wiring (not shown) is formed.

As shown in FIG. 9, a passivation film 17 is then formed on semiconductor substrate 1 so as to cover the wiring by, for example, the CVD method. As a result, wafer 2 on which semiconductor chips 4 shown in FIG. 1 is formed is obtained. Further, the rear surface of wafer 2 is subjected to a polishing treatment before dicing, thereby making the thickness of wafer 2 thinner.

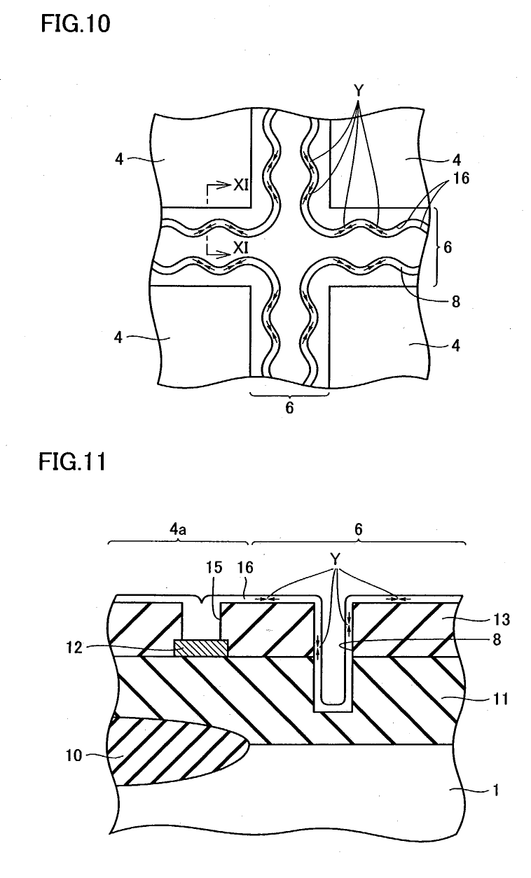

According to the above-mentioned manufacturing method for the wafer, corrugated groove 8 is formed first on each dicing line region 6. As shown in FIGS. 10 and 11, metal film (e.g. barrier metal) 16 is formed so as to cover the surface of corrugated groove 8 formed on dicing line region 6, whereby the film stress of metal film 16 is dispersed in multiple directions as indicated by arrow marks Y.

Particularly, since the surface area of corrugated groove 8 becomes larger, the region (area) of groove 8 capable of dispersing the film stress in multiple directions increases. As a result, even if the thickness of wafer 2 becomes thinner and tends to be influenced by the film stress, the stress acting on wafer 2 can be sufficiently relaxed and it is thereby possible to ensure reducing the warping of wafer 2.

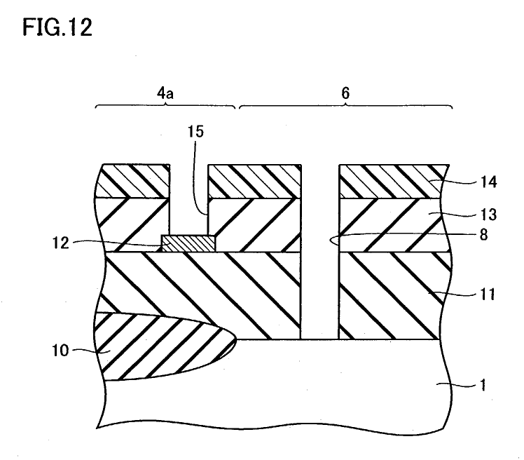

In the above-mentioned example, corrugated groove 8 which is formed up to the midway depth of silicon oxide film 11 has been described as one example of the corrugated groove as shown in FIG. 6. Alternatively, as shown in FIG. 12, corrugated groove 8 having such a depth to expose the surface of semiconductor substrate 1 may be formed.

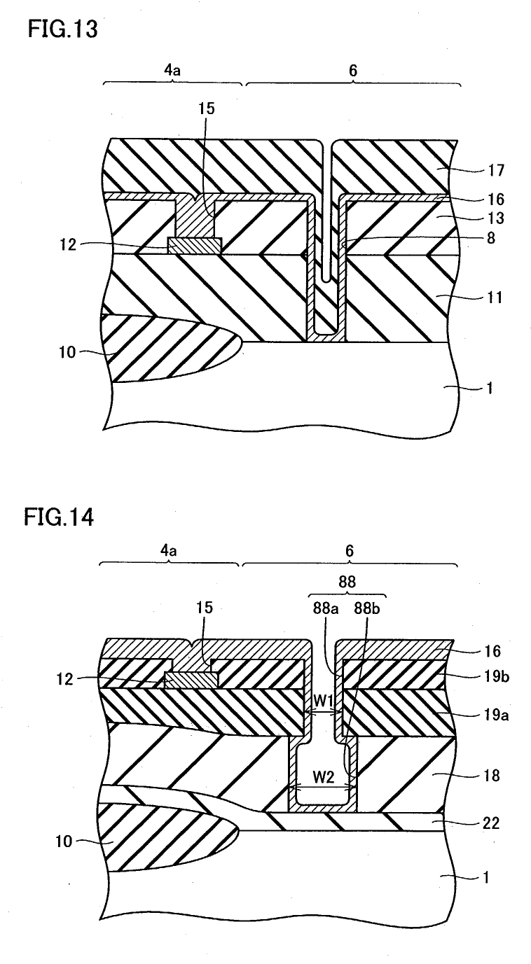

In the latter case, as shown in FIG. 13, the surface area of corrugated groove 8 further increases, whereby metal film 16 can further relax the stress acting on wafer 2 and the warping of wafer 2 can be further reduced.

Moreover, in a step shown in FIG. 12, if the corrugated groove is formed by, for example, anisotropic etching, an etching end point can be easily detected and the depth of corrugated groove 8 can be set approximately uniform throughout the surface of wafer 2. As a result, it is possible to suppress the change of the surface area of corrugated groove 8, to approximately and uniformly relax the stress acting on wafer 2 and to thereby ensure reducing the warping of wafer 2.

If semiconductor chip 4 is electrically measured in a wafer 2 state or if the film thickness of the film formed on wafer 2 is measured and wafer is held by an electrostatic chuck, it is possible to suppress the occurrence of an electrostatic chuck error that the wafer cannot be surely chucked by relaxing the warping of wafer 2. It is thereby possible to smoothly and electrically measure wafer 2.

Further, if a predetermined annealing treatment is performed to the wiring formed by metal film 16, it is possible to effectively radiate wafer 2 by forming metal film 16 on the surface of corrugated groove 8.

Additionally, by simultaneously executing the step of forming contact hole 15 and that of forming corrugated groove 8, it is possible to form corrugated groove 8 without adding a step.

Second Embodiment

A semiconductor chip mounting wafer and a manufacturing method therefor according to the second embodiment of the present invention will be described hereinafter. As already described above, a plurality of semiconductor chips 4, such as DRAM, partitioned by dicing line regions 6 are formed on wafer 2 (see FIG. 1).

A predetermined groove is formed on each dicing line region 6. As shown in FIG. 14, a groove 88 includes a groove section 88a which has a first width W1 and a groove section 88b which has a second width W2 larger than first width W1 in the cross section of groove 88.

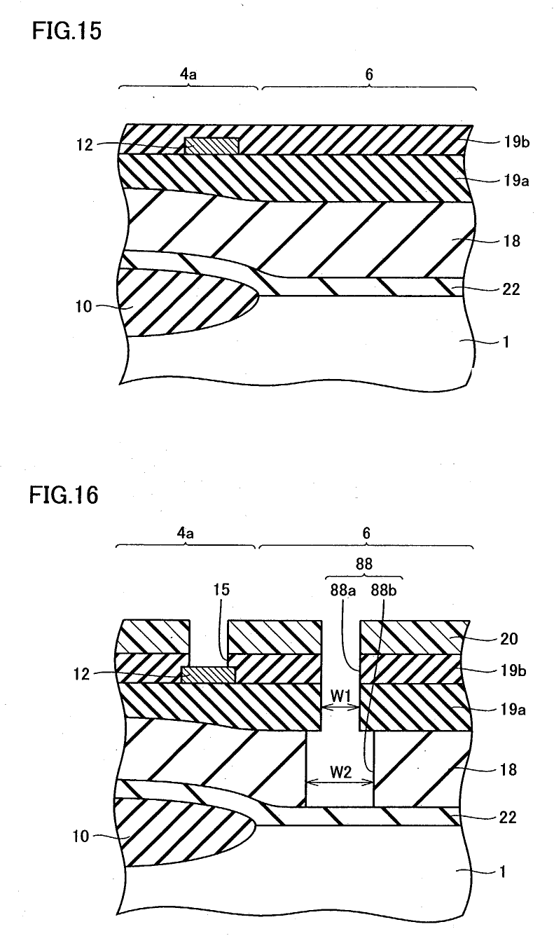

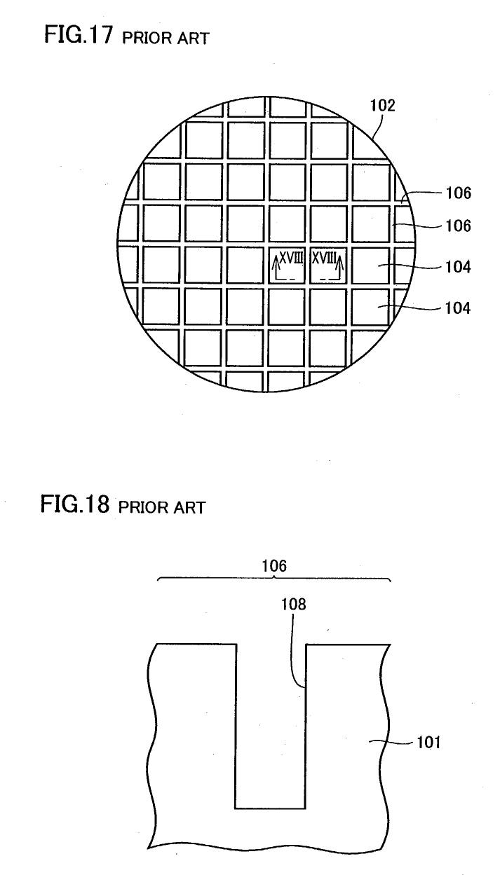

Next, a method for manufacturing the above-mentioned semiconductor chip mounting wafer will be described. After the step already described above and shown in FIG. 3, a silicon oxide film 22 is formed on semiconductor substrate 1 and a BPTEOS (Boro-Phospho-TetraEthyl-Ortho-Silicate-glass) film 18 is formed on silicon oxide film 22 by, for example, the CVD method as shown in FIG. 15.

A TEOS (Tetra-Ethyl-Ortho-Silicate-glass) film 19a is formed on BPTEOS film 18 by, for example, the CVD method. It is noted that BPTEOS film 18 is a film formed by doping a TEOS film with boron and phosphorus as impurities. Next, predetermined wiring 12 is formed on TEOS film 19a. A TEOS film 19b is further formed on TEOS film 19a so as to cover wiring 12 by the CVD method.

Next, as shown in FIG. 16, a predetermined photoresist 20 is formed on TEOS film 19b. Using photoresist 20 as a mask, TEOS films 19b and 19a and BPTEOS film 18 are subjected to anisotropic etching, whereby contact hole 15 which exposes the surface of wiring 12 is formed on chip formation region 4a.

In dicing region 6, on the other hand, groove 88 which exposes the surface of silicon oxide film 22 is formed. Under the same etching conditions, the etching rate of BPTEOS film 18 is faster than that of TEOS films 19b and 19a. Due to this, compared with TEOS films 19b and 19a, BPTEOS film 18 is greatly etched from the side surface of the groove section, which is gradually formed in BPTEOS film 18, toward a substantially horizontal direction.

In groove 88 thus completed, therefore, width W2 of groove section 88b formed in BPTEOS film 18 is larger than width Wl of groove section 88a formed in TEOS films 19a and 19b. As a result, the surface area of groove 88 is larger than that of a groove which would be formed to have equal width W1.

Next, predetermined metal film 16 is formed on the silicon oxide film so as to embed contact hole 15 by, for example, the sputtering method (see FIG. 14). This metal film 16 is provided to form a wiring electrically connected to wiring 12.

By performing predetermined photolithography and processing to metal film 16, a predetermined wiring (not shown) is formed. Next, as in the case of the step shown in FIG. 13, a passivation film (not shown) is formed on semiconductor substrate 1 so as to cover the predetermined wiring by, for example, the CVD method, whereby wafer 2 on which semiconductor chips 4 shown in FIG. 1 are formed is obtained. Furthermore, the rear surface of wafer 2 is subjected to a polishing treatment before dicing, thereby making the thickness of wafer 2 thinner.

According to the above-mentioned wafer manufacturing method, groove section 88a which is formed in TEOS films 19a and 19b and which has width W1 and groove section 88b which is formed in BPTEOS film 18 and which has width W2 are formed in groove 88 formed in dicing line region 6, whereby the surface area of groove 88 becomes larger than that of a groove which would be formed to have equal width W1. By forming metal film 16 so as to also cover the surface of groove 88, the region (an area) of groove 88 capable of dispersing the film stress increases.

As a result, even if the thickness of wafer 2 becomes thinner and tends to be influenced by the film stress, it is possible to sufficiently relax the stress acting on wafer 2 and to ensure reducing the warping of wafer 2.

Further, as described above, by reducing wafer warping, it is possible to suppress the occurrence of an electrostatic chuck error and to smoothly perform electrical measurement and the like to semiconductor chip 4.

In the second embodiment, a case where groove section 88a having width W1 is formed in an upper portion and groove section 88b having width W2 is formed in a lower portion has been described by way of example. Alternatively, by forming the TEOS film below the BPTEOS film, groove section 88a having width W1 may be formed in the lower portion and groove section 88b having width W2 may be formed in the upper portion.

Furthermore, insulating films having different etching characteristics have been described while taking the TEOS films and the BPTEOS film as an example. Alternatively, a nitride film, an oxide film (SOG film) formed by a spin-on-glass method, an oxide film formed by a high density plasma method and the like may be combined.

By appropriately combining these films, it is possible to form a groove having a larger surface area because of different etching rates. As a result, it is possible to reduce wafer warping and to prevent an electrostatic chuck error.

Moreover, as already described above, if a predetermined annealing treatment is performed to the wiring formed by metal film 16, it is possible to effectively radiate wafer 2 by forming metal film 16 on the surface of groove 88.

Furthermore, by simultaneously executing the step of forming contact hole 15 and that of forming groove 88, it is possible to form groove 88 without adding a step.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor chip mounting wafer comprising:
a plurality of chip regions each having a semiconductor chip formed thereon;
a dicing line region for cutting down said plurality of chip regions;
an insulating film formed so as to cover said plurality of chip regions and said dicing line region;
a corrugated groove section formed in a section of said insulating film located in said dicing line region; and
a predetermined layer formed on said insulating film including said corrugated groove, for forming said semiconductor chips.

2. The semiconductor chip mounting wafer according to claim 1, wherein
at least two said corrugated groove sections are arranged in said dicing line region located between the two adjacent chip regions in said plurality of chip regions.

3. A semiconductor chip mounting wafer comprising:
a plurality of chip regions each having a semiconductor chip formed thereon;
a dicing line region for cutting down said plurality of chip regions;
an insulating film formed so as to cover said plurality of chip regions and said dicing line region;
a groove section formed in a section of said insulating film located in said dicing line region; and
a predetermined layer formed on said insulating film including said groove section, for forming said semiconductor chips, wherein
said groove section includes:
a first section having a first width in a cross section of said groove section; and
a second section having a second width different from said first width.

4. The semiconductor chip mounting wafer according to claim 3, wherein
said insulating film includes:
a first layer having a predetermined etching characteristic; and
a second layer formed on said first layer, and having a different etching characteristic from that of said first layer,
said first section in said groove section is formed on said first layer, and
said second section is formed on said second layer.

5. The semiconductor chip mounting wafer according to claim 4, wherein
said second width is narrower than said first width.
